(19) United States
(12) Patent Application Publication
(10) Pub. No.: US 2007/0138639 A1
(43) Pub. Date: Jun. 21, 2007

(54) PAD STRUCTURE IN A SEMICONDUCTOR DEVICE AND A METHOD OF FORMING A PAD STRUCTURE

(76) Inventor: Young Wook Shin, Seoul (KR)

Correspondence Address: SHERR & NOURSE, PLLC, 620 HERNDON PARKWAY, SUITE 200, HERNDON, VA, 20170, US

(21) Appl. No.: 11/610,748

(22) Filed: Dec. 14, 2006

(30) Foreign Application Priority Data
Dec. 16, 2005 (KR) 10-2005-0124449

(51) Int. Cl. H01L 23/52

(52) U.S. Cl. 257/758

(57) ABSTRACT

A pad structure of a semiconductor device includes a plurality metal layers formed on a semiconductor substrate. An uppermost metal layer includes grooves.

The present application claims priority under 35 U.S.C. 119 and 35 U.S.C. 365 to Korean Patent Application No. 10-2005-0124449 (filed on Dec. 16, 2005), which is hereby incorporated by reference in its entirety.

### BACKGROUND

A semiconductor device pad may be used to electrically connect a chip to an outside interface. A pad may be formed as a bonding pad. A pad may be connected to a bump or a wiring bonding. A pad may be configured to contact probes during testing of a chip.

FIGS. 1 and 2 illustrate a plan view and a cross sectional view of a pad structure of a semiconductor device. As illustrated in FIGS. 1 and 2, a pad structure may include three levels of metal layers (e.g. metal layer 11, metal layer 13, and metal layer 15), via 21, and via 25.

First metal layer 11 may be formed over underlying insulating film 31. Underlying insulating layer 31 may be formed over semiconductor substrate 30. First interlayer insulating film 33 may be deposited over first metal layer 11. First metal layer 11 may have a rectangular pattern. A plurality of first vias 21 may be formed in first interlayer insulating film 33. First vias 21 may be distanced apart from each other.

Second metal layer 13 may be deposited over first interlayer insulating film 33 and first vias 21. Second metal layer 13 may have a rectangular pattern. A rectangular pattern of second metal layer 13 may be arranged perpendicular to a rectangular pattern of first metal layer 11. Then, a plurality of second vias 25 is formed in the second interlayer insulating film 35 to penetrate it. The second vias 25 are arranged distanced apart from each other and they are formed at locations not overlapping with where the first vias 21 are provided. Afterwards, a third metal layer 15 is formed on the second insulating film 35 and the second vias 25 to have a rectangular pattern which is perpendicularly dislocated from the rectangular pattern of second metal layer 13.

In a pad structure illustrated in FIG. 1, portions of interlayer insulting film 33 and interlayer insulating film 35 do not overlap with each other between the metal layer 11, metal layer 13, and metal layer 15. If a planarizing process is unstable during semiconductor manufacturing, there may be abnormal formations of photoresists, polymers, or similar materials. Abnormal formations in a pad structure may result in undesirable foreign substances remaining on a pad structure and/or color differences, which may result in pad defects.

### SUMMARY

Embodiments relate to a semiconductor device comprising a pad structure and/or methods of forming a pad structure. Embodiments relate to a pad structure that may prevent process failure during formation of a pad. Embodiments may have advantages for packaging processes.

In embodiments, a pad structure of a semiconductor device may include at least one of: a plurality of metal layers formed over a semiconductor substrate; a plurality of insulating films which insulate a plurality of metal layers from each other; at least one via formed in a plurality of interlayer insulating films which electrically connect a plurality metal layers with each other; and a plurality of grooves formed in a surface of an uppermost metal layer of a plurality of metal layers.

Embodiments relate to a method of forming a pad structure in a semiconductor device, which may include at least one of the following steps: forming a pad structure that includes at least one metal layer over a semiconductor substrate; forming at least one interlayer insulating film interposed between at least one metal layer to insulate the at least one metal layer from each other; forming at least one via formed in at least one interlayer insulating film to electrically connect at least one metal layer; and forming at least one groove in a surface of an uppermost metal layer of at least one metal layer.

### BRIEF DESCRIPTION OF THE DRAWINGS

FIGS. 1 and 2 show a schematic plan view and a schematic cross sectional view illustrating a pad structure of a semiconductor device.

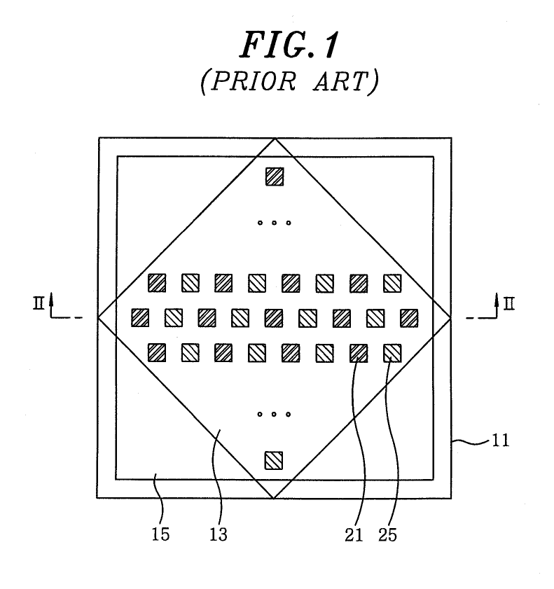

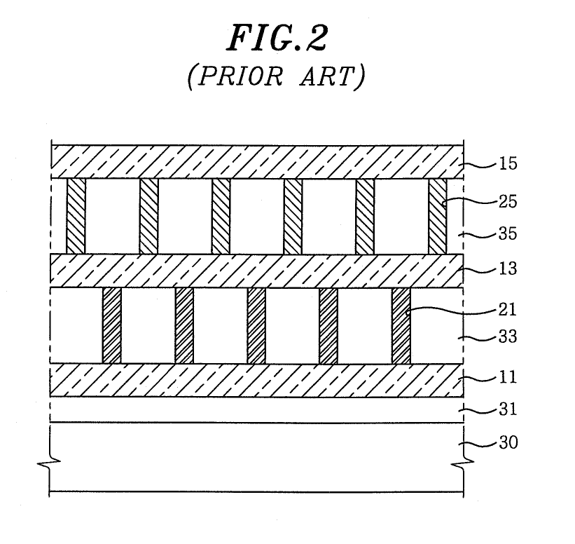

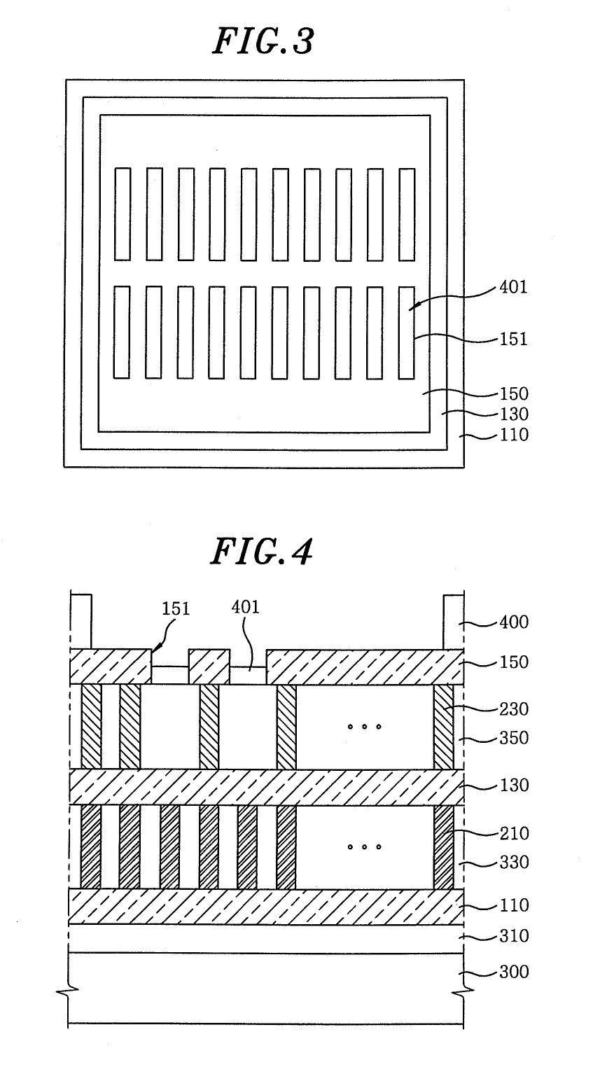

Example FIGS. 3 and 4 show a schematic plan view and a schematic cross sectional view illustrating a pad structure of a semiconductor device, in accordance with embodiments.

### DETAILED DESCRIPTION

Example FIGS. 3 and 4 illustrate a schematic plan view and a schematic cross sectional view of a pad structure of a semiconductor device and methods of manufacturing, according to embodiments. As illustrated in FIGS. 3 and 4, a pad structure may include at least one of: metal layer 110, metal layer 130, and metal layer 150 formed over underlying insulting film 310 and semiconductor substrate 300; interlayer insulating film 330 between metal layer 110 and metal layer 130; interlayer insulating film 350 between metal layer 130 and metal layer 150; vias 210 in interlayer insulating film 330; and vias 230 in interlayer insulating film 350.

Vias 210 may electrically connect the metal layer 110 and metal layer 130. Vias 230 may electrically connect metal layer 130 and metal layer 150. Metal layer 150 may include grooves 151 formed on its surface, in accordance with embodiments.

First metal layer 110 may be formed to have a rectangular pattern. First interlayer insulating film 330 may be deposited over first metal layer 110. First interlayer insulating film 330 may be planarized through a planarizing process. Examples of planarizing processes are chemical mechanical polishing (CMP), a SOG etch back process, an etch back process using a photoresist pattern, or similar processes. In embodiments, planarization of first interlayer insulating film 330 may improve the margin of the formation of metal layers.

Vias 210 may be formed in first interlayer insulating film 330. Vias 210 may be arranged apart from each other in non-uniform intervals, in accordance with embodiments. In embodiments, vias 210 may be arranged in regular intervals in some regions and at irregular intervals in other regions. Vias 210 may be formed by forming via holes in first interlayer insulating film 330 and filling the via holes with conductive material. An example of conductive material that fills via holes is tungsten silicide. Conductive material may be planarized to form vias 210.

Second metal layer 130 may be formed in a rectangular-shaped pattern. Second metal layer 130 may be similar to a rectangular-shaped pattern of first metal layer 110. A rectangular-shaped pattern of second metal layer 130 may be aligned vertically with a rectangular-shaped pattern of first metal layer 110. Second interlayer insulating film 350 may be deposited over second metal layer 130.

Second interlayer insulating film 350 may be planarized through a planarizing process. Examples of a planarizing process include chemical mechanical polishing (CMP), an SOG etch back process, an etch back process using a photoresist pattern, or similar processes. In embodiments, planarization of second interlayer insulating film 350 may improve the margin of metal layers formed over second interlayer insulating film 350. Vias 230 may be formed in second interlayer insulating film 350. In embodiments, vias 230 may be arranged in non-uniform intervals. In embodiments, vias 230 may be arranged in regular intervals in some regions and arranged in irregular intervals in other regions. Vias 230 may be formed by forming via holes in second interlayer insulating film 350 and filling the via holes with conductive material. An example of conductive material that fills via holes is tungsten silicide. Conductive material may be planarized to form vias 230. In embodiments, there are regions where vias 230 do not overlap with vias 210.

Third metal layer 150 may be formed in a rectangular-shaped pattern aligned vertically with a rectangular-shaped pattern of second metal layer 130.

In embodiments, vias 210 and vias 230 are set up to connect to metal layer 110, metal layer 130, and metal layer 150. In embodiments, vias 210 and vias 230 may be arranged to not to connect to metal layer 110, metal layer 130, and metal layer 150. In embodiments, vias 210 and vias 230 may relieve stress imposed on a pad structure when conducting tests to investigate problems of a semiconductor product. In embodiments, vias 210 and vias 230 may prevent the adhesions of metal layer 110, metal layer 130, and metal layer 150 from loosening. In embodiments, vias 210 and vias 230 may relieve mechanical stress from a bonding process that connects a pad with a lead frame of packaging of a semiconductor product.

Third metal layer 150 may include grooves 151 on its surface, in accordance with embodiments. Grooves 151 may be arranged in a regular manner. Grooves 151 may be arranged such that vias 230 are not exposed through grooves 151. In embodiments, grooves 151 may prevent probes from sliding on metal layer 150 (e.g. during a probe test). In embodiments, grooves 151 may relieve mechanism stress imposed on a pad structure from probes.

In embodiments, passivation layer 400 may be formed in a region where metal layer 150 is exposed. Residual portions 401 of passivation layer 400 may cover grooves 151. In embodiments, etching may selectively etch residual portions 401 such that the surface of metal layer 150 is exposed. In embodiments, through etching, residual portions 401 may be etched to some degree and grooves 151 may be partially exposed.

In embodiments, a groove pattern formed on an uppermost metal layer may relieve stress imposed on a pad during a test process that inspects the quality of a product. In embodiments, if a test is carried out smoothly, mechanical stress generated during packaging of a product may be reduced. In embodiments, grooves may prevent probes from sliding on the surface of a pad. In embodiments, the size of a pad may be reduced, which may allow the size of a product chip to be reduced.

It will be apparent to those skilled in the art that various modifications and variations can be made to embodiments. Thus, it is intended that embodiments cover modifications and variations thereof within the scope of the appended claims.

What is claimed is:

1. An apparatus comprising:
at least two metal layers formed over a semiconductor substrate;
at least one insulating film formed between the at least two metal layers;
at least one via formed in said at least one insulating film; and
at least one groove formed in said at least two metal layers.

2. The apparatus of claim 1, wherein the apparatus is a pad structure of a semiconductor device.

3. The apparatus of claim 1, said at least one groove is formed in a surface of an uppermost metal layer of said at least two metal layers.

4. The apparatus of claim 1, wherein:
said at least two metal layers each have rectangular-shaped patterns; and
said at least two metal layers are aligned vertically with each other.

5. The apparatus of claim 1, comprising a passivation layer which is configured to expose at least a portion of an uppermost metal layer of said at least two metal layers.

6. The apparatus of claim 5, wherein the passivation layer comprises a residual portion in said at least one groove.

7. The apparatus of claim 6, wherein the residual portion is below the surface of the uppermost metal layer.

8. A method comprising:
forming at least two metal layers over a semiconductor substrate;
forming at least one insulating film between the at least two metal layers;
forming at least one via in said at least one insulating film; and
forming at least one groove in said at least two metal layers.

9. The method of claim 8, wherein the method forms a pad structure of a semiconductor device.

10. The method of claim 8, comprising forming a passivation layer that exposes at least a portion of an uppermost metal layer of said at least two metal layers.

11. The method of claim 10, comprising selectively etching a residual portion of the passivation layer.

12. The method of claim 11, wherein the residual portion is in said at least one groove.

13. The method of claim 12, wherein the residual portion is below the surface of the uppermost metal layer.

14. A pad structure of a semiconductor device comprising:
a first metal layer formed over a semiconductor substrate;
a first interlayer insulating film formed over the first metal layer;
a first plurality of vias formed in the first interlayer insulating film;
a second metal layer formed over the first interlayer insulating film;
a second interlayer insulating film formed over the second metal layer;
a second plurality of vias formed in the second interlayer insulating film; and
a third metal layer formed over the second interlayer insulating film, wherein the third metal layer comprises a plurality of grooves.

15. The pad structure of claim 14, wherein said first plurality of vias and said second plurality of vias are aligned.

16. The pad structure of claim 14, wherein said first plurality of vias are arranged irregularly.

17. The pad structure of claim 14, wherein said second plurality of vias are arranged irregularly.

18. The pad structure of claim 14, wherein said first plurality of vias and said second plurality of vias are arranged irregularly.

19. The method of claim 14, wherein a portion of said first plurality of vias are arranged regularly and a portion of said first plurality of vias are arranged irregularly.

20. The method of claim 14, wherein a portion of said second plurality of vias are arranged regularly and a portion of said second plurality of vias are arranged irregularly.
